(19) United States
(12) Patent Application Publication
(10) Pub. No.: US 2026/0362842 A1
(43) Pub. Date: Nov. 12, 2026

(54) METHOD FOR PREPARING SOLAR CELL AND SOLAR CELL

(71) Applicant: ZHEJIANG JINKO SOLAR CO., LTD., HAINING (CN)

(72) Inventors: Ruhao WANG, HAINING (CN); Minkun JIN, HAINING (CN); Xiangning LI, HAINING (CN); Zhenzhen LEI, HAINING (CN); Wei CUI, HAINING (CN); Jingsheng JIN, HAINING (CN); Bike ZHANG, HAINING (CN); Xin LIU, HAINING (CN)

(21) Appl. No.: 19/392,539

(22) Filed: Nov. 18, 2025

(30) Foreign Application Priority Data
May 12, 2025 (CN) 202510608254.X

(51) Int. Cl. H10F 71/00

(52) U.S. Cl. CPC H10F 71/129; H10F 71/134

(57) ABSTRACT

A method for preparing a solar cell is provided. The method includes: providing an initial split cell piece with a cross-section; subjecting the cross-section to an oxidation treatment to obtain an oxide layer; preparing a hydrogen-containing passivation layer on a surface of the oxide layer away from the cross-section; and subjecting a surface of the hydrogen-containing passivation layer away from the oxide layer to a hydrogen-passivation activation treatment, so as to release hydrogen ions in the hydrogen-containing passivation layer to the cross-section to obtain a passivated split cell piece.

### CROSS-REFERENCE TO RELATED APPLICATION

This application claims priority to Chinese patent application No. 202510608254.X, filed on May 12, 2025, the content of which is hereby incorporated by reference in its entirety.

### TECHNICAL FIELD

The present disclosure relates to the field of solar cell, in particular, to a method for preparing a solar cell and a solar cell.

### BACKGROUND

Currently, a half-cut method for preparing a cell or a multi-cut method for preparing a cell have advantages of reducing an internal resistance of solar cells and improving the conversion efficiency of solar cells, and is widely used in the preparation process of solar cells. In the related art, in the process of preparing and assembling a half-cut cell or a multi-cut cell, a conventional process is to divide a cell into multiple pieces by a laser scribing technology, and deposit a hybrid passivation layer on a cross-section by an atomic layer deposition (ALD) technology.

### SUMMARY

An object of the embodiments in the present disclosure is to provide a method for preparing a solar cell and a solar cell, so as to improve a passivation effect of the cross-section and improve performances of the split cell.

In order to solve the technical problem above, a method for preparing a solar cell is provided in embodiments of the present disclosure. The method includes: providing an initial split cell with a cross-section; subjecting the cross-section to an oxidation treatment to obtain an oxide layer; preparing a hydrogen-containing passivation layer on a surface of the oxide layer away from the cross-section; and subjecting a surface of the hydrogen-containing passivation layer away from the oxide layer to a hydrogen-passivation activation treatment, so as to release hydrogen ions in the hydrogen-containing passivation layer to the cross-section to obtain a passivated split cell.

A solar cell is further provided in the present disclosure, which includes the passivated split cell prepared by the method for preparing the solar cell described above.

In some embodiments, the step of subjecting the cross-section to an oxidation treatment to obtain an oxide layer includes: subjecting the cross-section to a first preheating treatment and preparing an initial oxide layer on the cross-section; and, subjecting the initial oxide layer to a second oxidation treatment so that the initial oxide layer is oxidized to the oxide layer.

In some embodiments, the step of subjecting the cross-section to a first preheating treatment includes: before the first preheating treatment, disposing the cross-section in an ozone environment to perform the first preheating treatment.

In some embodiments, in the step of disposing the cross-section in an ozone environment to perform the first preheating treatment, a concentration of ozone is in a range of 800 ppm to 1200 ppm.

In some embodiments, the step of second oxidation treatment includes: subjecting the initial oxide layer to a first laser treatment in an oxygen-rich environment.

In some embodiments, the oxygen-rich environment includes an oxygen-containing liquid environment, and the oxygen-containing liquid is selected from the group consisting of hydrogen peroxide solution, ozone aqueous solution, and any combination thereof.

In some embodiments, the step of subjecting the initial oxide layer to the first laser treatment in the oxygen-rich environment includes: spraying a hydrogen peroxide solution on the cross-section, and subjecting the initial oxide layer to the first laser treatment at the same time, wherein a mass fraction of the hydrogen peroxide solution is in a range of 30%-40%.

In some embodiments, the step of the hydrogen-passivation activation treatment includes a second laser treatment, and an energy of the second laser treatment is lower than an energy of the first laser treatment.

In some embodiments, before the step of subjecting the surface of the hydrogen-containing passivation layer away from the oxide layer to the hydrogen-passivation activation treatment, the method for preparing the solar cell includes: subjecting the surface of the hydrogen-containing passivation layer away from the oxide layer to a second preheating treatment.

In some embodiments, a thickness of the hydrogen-containing passivation layer is greater than a thickness of the oxide layer.

In some embodiments, a thickness of the oxide layer is in a range of 5 nm to 10 nm, and a thickness of the hydrogen-containing passivation layer is in a range of 5 nm to 50 nm.

In some embodiments, a power of the first laser treatment is greater than a power of the second laser treatment.

In some embodiments, a temperature of the first laser treatment is higher than a temperature of the second laser treatment.

In some embodiments, a power of the first laser treatment is in a range of 150 W to 300 W, and a power of the second laser treatment is in a range of 80 W to 150 W.

In some embodiments, a temperature of the first laser treatment is in a range of 500 degrees centigrade to 1000 degrees centigrade, and a temperature of the second laser treatment is in a range of 300 degrees centigrade to 750 degrees centigrade.

In some embodiments, a scanning speed of the first laser treatment is in a range of 1000 mm/s to 30000 mm/s; and a scanning speed of the second laser treatment is in a range of 1000 mm/s to 30000 mm/s.

In some embodiments, a temperature of the second preheating treatment is lower than a temperature of the first preheating treatment.

In some embodiments, the temperature of the first preheating treatment is in a range of 100 degrees centigrade to 300 degrees centigrade; and the temperature of the second preheating treatment is in a range of 50 degrees centigrade to 100 degrees centigrade.

In some embodiments, a time of the first preheating treatment is longer than a time of the second oxidation treatment.

In some embodiments, the time of the first preheating treatment is in a range of 600 s to 900 s; and the time of the second oxidation treatment is in a range of 100 s to 500 s.

Details of one or more embodiments of the present application are presented in the following accompanying drawings and description in order to make other features, purposes and advantages of the present application more concise and understandable.

### BRIEF DESCRIPTION OF THE DRAWINGS

One or more embodiments are exemplarily illustrated by the figures in the corresponding drawings. These exemplary illustrations do not constitute limitations on the embodiments. Components bearing the same reference numerals in the drawings are intended to represent similar components. Unless otherwise stated, the drawings are not intended to impose any limitations on scale.

FIG. 1 is a structural schematic diagram of micro-scale crack at a cross-section of the split cell in the related art.

FIG. 2 is a structural schematic diagram of a hybrid passivation layer film in the related art.

FIG. 3 is a schematic diagram of a solar cell, in which the solar cell is equally cut into two pieces.

FIG. 4 is a schematic diagram of a solar cell, in which the solar cell is equally cut into four pieces.

FIG. 5 is a structural schematic diagram of a solar cell obtained after the first preheating treatment in an embodiment of the present disclosure.

FIG. 6 is a structural schematic diagram of a solar cell obtained after the second oxidation treatment in an embodiment of the present disclosure.

FIG. 7 is a structural schematic diagram of a solar cell after preparing the hydrogen-containing passivation layer in an embodiment of the present disclosure.

FIG. 8 is a structural schematic diagram of a solar cell obtained after the hydrogen-passivation activation treatment in an embodiment of the present disclosure.

FIG. 9 is a structural schematic diagram of a hydrogen-containing passivation layer in an embodiment of the present disclosure.

### DETAILED DESCRIPTION

In the related art, the passivation effect of the split cell is poor, resulting in poor performances of the solar cell.

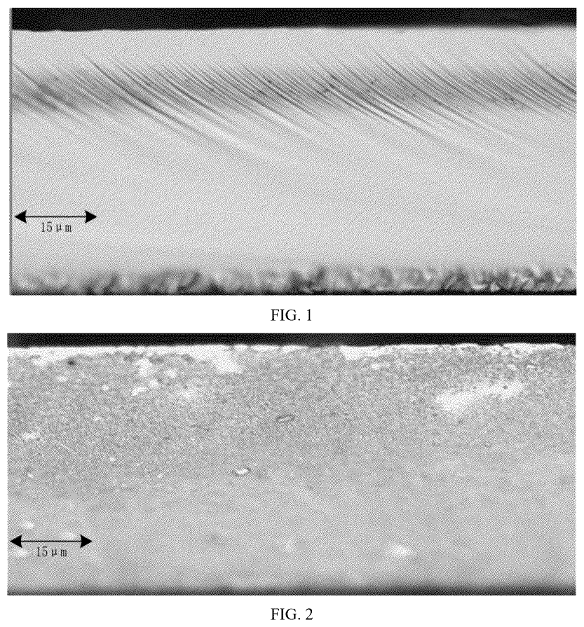

In the method for preparing the split cell in the related art, a conventional process includes: dividing a cell into two symmetrical pieces or multiple pieces by a laser scribing technology, depositing a hybrid passivation layer on a cross-section to passivate the cross-section, encapsulating and welding. However, in the related art, the laser scribing technology may cause heat-affected zones and mechanical damage zone on the micrometer scale. FIG. 1 is a structural schematic diagram of micro-scale crack at a cross-section of the split cell in the related art. Referring to FIG. 1, a great amount of dangling bonds are exposed in the micro-scale crack and form a composite reaction center, and the internal defect in the damage zone should be repaired by a certain means to improve the power of the component. In the related art, the hybrid passivation layer is deposited by ALD technology. Referring to FIG. 2, FIG. 2 is a structural schematic diagram of a hybrid passivation layer film in the related art. However, the ALD technology is generally applied to passivate a smooth surface, a surface of the cross-section of the split cell is rough and the defect in the damage zone is serious, it is difficult to effectively passivate the underlying damage zone merely by the low-temperature ALD technology. In addition, a large scale of hydrogen ions are concentrated in the film after the low-temperature deposition treatment, the damage zone of the cross-section is not effectively repaired. Thus, the hybrid passivation layer obtained by low-temperature deposition in FIG. 2 is poor in density and passivation effect.

In order to improve the passivation effect of a cross-section of a split cell and improve performances of the cell, a method for preparing a solar cell is provided in embodiments of the present disclosure. In embodiments of the present disclosure, a cross-section of the initial split cell is subjected to oxidation treatment to obtain an oxide layer, so as to saturate dangling bonds on the cross-section and improve the passivation effect; after the hydrogen-containing passivation layer is deposited on the oxide layer, a surface of the hydrogen-containing passivation layer away from the oxide layer is subjected to a hydrogen-passivation activation treatment, so as to release the hydrogen ions in the hydrogen-containing passivation layer to the cross-section, passivate a damage zone of the cross-section and repair internal defects of the cross-section, and obtain a passivated split cell, thereby improving a passivation effect of the split cell and improve the performance of the split cell.

In the description of the embodiments of the present disclosure, technical terms such as “first” and “second” are used solely to distinguish different objects and should not be construed as indicating or implying relative importance, nor as implying the number, specific sequence, or hierarchical relationship of the technical features indicated. In the description of the embodiments of the present disclosure, “multiple” means two or more, unless otherwise explicitly specified.

The term “embodiment” as used herein implies that the specific features, structures, or characteristics described in connection with an embodiment may be included in at least one embodiment of the present disclosure. The occurrence of this phrase at various locations in the specification does not necessarily refer to the same embodiment, nor does it denote independent or alternative embodiments that are mutually exclusive with other embodiments. It is explicitly and implicitly understood by those skilled in the art that the embodiments described herein may be combined with other embodiments.

In the description of the embodiments disclosed herein, the term “and/or” merely describes the relationship between associated objects, indicating that three types of relationships may exist. For example, “A and/or B” may represent the following three scenarios: A exists, both A and B exist, or B exists. Additionally, the character “/” in this document generally indicates that the relationship between the preceding and following associated objects is “or.”

In the description of the embodiments of the present disclosure, the term “multiple” refers to two or more (including two). Similarly, “multiple sets” refers to two or more sets (including two sets), and “multiple pieces” refers to two or more pieces (including two pieces).

In the description of the embodiments of the present disclosure, the orientation or positional relationships indicated by technical terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” are based on the orientation or positional relationships shown in the drawings. These are provided solely for the purpose of facilitating the description of the embodiments of the present disclosure and simplifying the description, and are not intended to indicate or imply that the devices or elements referred to must have a specific orientation, be constructed in a specific orientation, or operate in a specific orientation. Therefore, they should not be construed as limitations on the embodiments of the present disclosure.

In the description of the embodiments of the present disclosure, unless otherwise explicitly specified and limited, technical terms such as “mounted,” “connected,” “coupled,” and “fixed” should be interpreted broadly. For example, a connection may be fixed or detachable, or may be integral; it may be mechanical or electrical; it may be direct or indirect via an intermediary; it may represent internal communication between two components or an interactive relationship between them. Those skilled in the art will understand the specific meaning of the above terms in the context of the embodiments disclosed herein based on the particular circumstances.

In the drawings corresponding to the embodiments of the present disclosure, layer thicknesses and areas are magnified for better understanding and ease of description. When describing a component (such as a layer, film, region, or substrate) being on or on the surface of another component, the component may be “directly” located on the surface of the other component, or a third component may exist between the two components. Conversely, when describing a component on the surface of another component, or when another component is formed or disposed on the surface of a component, it indicates that no third component exists between them. Furthermore, when describing a component as “roughly” formed on another component, it means the component is not formed over the entire surface (or front surface) of the other component, nor is it formed along the entire edge of the surface.

In the description of the embodiments of the present disclosure, when a component “includes” another component, unless otherwise specified, other components are not excluded, and other components may further be included. Furthermore, when a component such as a layer, film, region, or plate is referred to as being “on/located on” another component, it may be “directly on” another component (i.e., located on the surface of another component with no other components between them), or another component may exist between them. Furthermore, when a layer, film, region, plate, or similar component is described as being “directly on” another component, or when such a component is located on the surface of another component, it indicates that no other components are present between them.

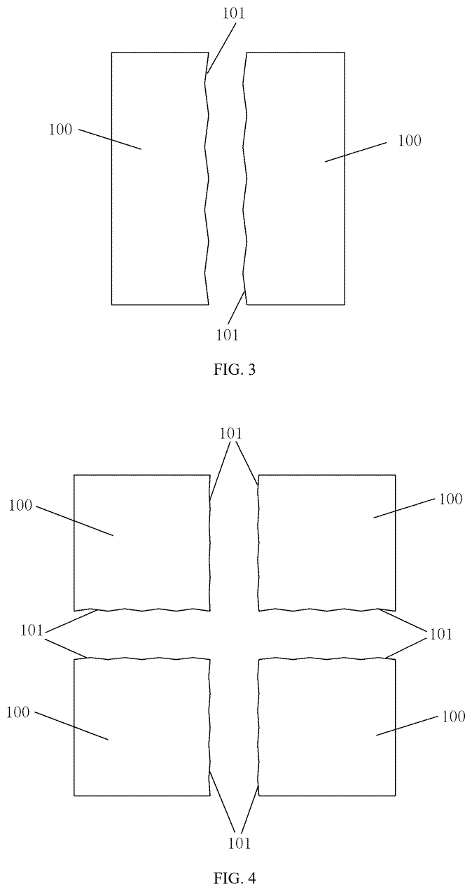

FIGS. 3 to 8 are structural schematic diagrams of the solar cell in different steps of the method for preparing the solar cell in embodiments of the present disclosure.

FIG. 3 is a schematic diagram of a solar cell, in which the solar cell is equally cut into two pieces. FIG. 4 is a schematic diagram of a solar cell, in which the solar cell is equally cut into four pieces. In the present embodiment, the initial split cell 100 includes a cross-section 101.

In the present disclosure, the initial split cell 100 is obtained by method of laser scribing. A laser beam with a high power density is applied to irradiate the electrode material of the solar cell, so that the electrode material of the solar cell is rapidly heated to be melted, vaporized or burned, thereby cutting the solar cell to form the initial sliced cell 100. In some embodiments, the initial split cell 100 can be prepared by other cutting methods, such as blade cutting, stamping cutting, diamond wire cutting, etc., as long as the cross-section 101 of the initial split cell 100 includes the micro-scale crack as shown in FIG. 1.

The solar cell includes a substrate, a P-N junction, a front electrode, a rear electrode, a passivation layer and an anti-reflection layer. The substrate is a layer of the solar cell which has an effect of generating charge carriers and supporting. The substrate is selected from monocrystalline silicon and/or polycrystalline silicon. The P-N junction includes a P-type region and an N-type region, and is configured for separating photon-generated carriers. The front electrode is configured for collecting photon-generated carriers and transferring the electric current, and is generally made of silver paste by printing. The rear electrode is configured for collecting the electric current and provide an electric field, and is generally made of aluminum or other metal materials. The passivation layer is a film coated on a front surface of the solar cell and a rear surface of the solar cell, and is configured for reducing surface recombination and improving the battery efficiency. The anti-reflection layer is configured for reducing reflection of the light and improve absorptivity of the light, and is generally made of materials such as silicon nitride (SiNₓ) and the like.

In a production process of the photovoltaic cell, a cell slicing process is performed in a back-end process of cell production, that is, after a basic process is completed on the cell, the cell is sliced, and the basic process of the cell includes steps such as texturing, diffusion, coating, screen printing, and sintering. Before the cell are sliced, a requirement of a user for a photovoltaic module needs to be obtained, and the cells are sliced according to the requirement of the user to the photovoltaic module, so as to adapt to photovoltaic modules of different sizes. After the cell is sliced, the split cells are assembled to form the photovoltaic module.

The solar cell is sliced to form the initial split cell 100 of the present embodiment. In the present embodiment, the initial split cell may be a half-cut cell or a multi-cut cell, which may be set according to actual needs. When the initial sliced solar cell 100 is a multi-cut cell, only one side of the initial split cell 100 includes a cross-section. Referring to FIG. 3, FIG. 3 is a schematic diagram of a solar cell, in which the solar cell is equally cut into two pieces, AND the initial split cell 100 merely include one cross-section 101. Referring to FIG. 4, FIG. 4 is a schematic diagram of a solar cell, in which the solar cell is equally cut into four pieces, and the initial split cell may include two adjacent cross-sections 101. In the present embodiment, the initial split cell 100 includes a cross-section 101. In the embodiments of the present disclosure, the initial split cell may be a six-cut cell, an eight-cut cell and the like, and the number of the split cells may be set according to actual needs.

Referring to FIG. 3, in the present embodiment, the initial split cell segmented cell 100 of a half-cut cell is taken as an example. Specifically, only one side of the initial split cell 100 (i.e., the right side in FIG. 3) includes a cross-section 101. In practical applications, when the initial split cell 100 are multi-cut cells, the other sides of the initial split cell 100 (i.e., the left side, the top surface, and the bottom surface in FIG. 3) may also include a cut cross-sections 101.

In the present embodiment, the initial split cell 100 may include a substrate, a P-N junction, a front electrode, a rear electrode, a passivation layer and an anti-reflection layer. Since the initial split cell 100 are sliced, a single-string current can be reduced, a current loss can be reduced, and anti-mechanical load performance of the photovoltaic module can be improved.

In the present disclosure, since the initial split cell 100 may include the micro-scale crack as shown in FIG. 1, a great amount of Si—SiO₂ can be exposed and define composite reaction centers, resulting in an excessively large roughness of the cross-section 101 and serious damage in the damage zone. Referring to FIG. 2, in the related art, the hybrid passivation layer cannot significantly repair the damage zone of the cross-section 101, resulting in poor density of the hybrid passivation layer and poor passivation of the hybrid passivation layer, thereby resulting in poor passivation effect of the cross-section of the initial split cell 100 after scribing.

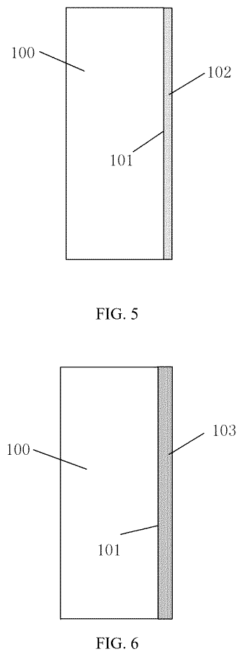

In order to improve the passivation effect of the cross-section of the initial split cell 100, referring to FIGS. 5 and 6, the cross-section 101 is subjected to oxidation treatment to form a oxide layer 103.

In the present disclosure, the cross-section of the initial split cell 100 is subjected to oxidation treatment to form the oxide layer 103, the surface of the cross-section 101 of the initial split cell 100 is effectively passivated, composition of the charge carriers is reduced and the passivation effect of the cross-section 101 of the initial split cell 100 is improved. At the same time, the oxide layer 103 can prevent impurity atoms from diffusing into a silicon substrate of the initial split cell 100, and avoid atoms except for hydrogen ions from diffusing to the silicon substrate in the subsequent hydrogen-passivation activation treatment, thereby maintaining a good passivation effect of the cross-section 101 of the initial split cell 100.

In the present disclosure, silicon oxide is obtained by subjecting the part of the silicon substrate at the cross-section 101 of the oxide layer 103 to oxidation treatment. After the cross section 101 is oxidized, a dense oxide layer 103 (i.e., silicon oxide) is generated on the cross-section 101 to fully saturate the Si—SiO₂ interface dangling bonds, thereby improving the passivation effect of the oxide layer 103.

The higher the density of the oxide layer 103, the better the passivation effect on the cross-section 101 of the initial split cell 100. Therefore, to further enhance the passivation effect on cross-section 101, performs two oxidation treatments are provided in the present disclosure: a first preheating treatment and a second oxidation treatment, which increases the density of the oxide layer 103.

Referring to FIG. 5, FIG. 5 is a structural schematic diagram of a solar cell obtained after the first preheating treatment in an embodiment of the present disclosure. In the present disclosure, the cross-section 101 may be subjected to a first preheating treatment to form an initial oxide layer on the cross-section 101.

In order to reduce an actual power of the subsequent first laser treatment, so as to reduce the negative effect of heat injure of the first laser treatment on the cross-section 101. In the present embodiment, before the first laser treatment, the cross-section 101 is subjected to the first preheating treatment to form the initial oxide layer 102 on the cross-section. Before performing the first laser treatment, the cross-section 101 is firstly subjected to the first preheating treatment to form the initial oxide layer 102, which is equivalent to forming part of the oxide layer 103 in advance, reducing the time for the subsequent first laser treatment to form the oxide layer 103 and improving the efficiency of the first laser treatment. In addition, the temperature of the cross-section 101 can also be preheated to the first preset temperature to reduce the actual power of the subsequent first laser treatment, thereby reducing the negative effect of heat injure of the first laser treatment on the cross section 101, and improving the passivation effect of the oxide layer 103.

In the present embodiment, before the first preheating treatment, the cross-section 101 of the initial split cell 100 can be disposed in a fixed fixture in an ozone environment to perform the first preheating treatment. A concentration of the ozone is in a range of 800 ppm to 1200 ppm, for example, 800 ppm, 900 ppm, 1000 ppm, 1100 ppm or 1200 ppm. In the present embodiment, by setting the concentration of ozone within the range above, on one hand, a rich oxygen environment is provided for the preheating oxidation of cross-section 101, which not only enhances the efficiency of the first preheating treatment but also ensures the uniform thickness and density of the generated initial oxide layer 102. On the other hand, excessive oxidation of cross-section 101 caused by overly high ozone concentrations can be avoided, the probability of defects arising caused by excessive oxidation can be reduced, and thus, the performance of the resulting split cell (such as reducing recombination, enhancing carrier transport, increasing open-circuit voltage and fill factor, and boosting power output) can be improved.

Additionally, as a potent oxidizing agent, ozone can rapidly decompose various pollutants, achieving a high level of cleanliness on cross-section 101. By setting the concentration of ozone within the range in the present embodiment, impurities and organic contaminants on the cross-section 101 can be effectively removed while preventing damage to the cross-section 101.

In some embodiments, the temperature of the first preheating treatment is in a range of 100 degrees centigrade to 300 degrees centigrade, for example 100 degrees centigrade, 150 degrees centigrade, 200 degrees centigrade, 250 degrees centigrade or 300 degrees centigrade. By setting the temperature of the first preheating treatment within the range above, on the one hand, the temperature of the cross-section 101 can be quickly preheated to the first preset temperature, the actual power of the subsequent first laser treatment can be reduced, and the cross-section 101 is prevented from being damaged due to the excessive power of the first laser treatment; on the other hand, the temperature of the cross-section 101 is prevented from changing quickly due to an excessive high preheating temperature, the temperature of the cross-section 101 is ensured to be uniformly distributed, and the performance difference caused by local overheating or supercooling is reduced. The cross-section 101 with a uniform temperature is provided for the subsequent first laser treatment, the density of the generated oxide layer 103 is improved, and the passivation effect of the oxide layer 103 is improved.

In some embodiments, a time of the first preheating treatment is in a range of 600 s to 900 s, for example, 600 s, 650 s, 700 s, 750 s, 800 s, 850 s, or 900 s. By setting the time of the first preheating treatment within the range above, on the one hand, it is ensured that the temperature of the cross-section 101 after the first preheating treatment is uniform, the density of the oxide layer 103 generated by the first laser treatment is improved; and on the other hand, the problem of performance degradation of the generated split cell caused by excessively long time of the first preheating treatment is avoided, and the performance of the split cell is improved.

In the present embodiment, after the cross-section 101 of the initial split cell 100 is subjected to the first preheating treatment, an initial oxide layer 102 is obtained on the cross-section 101, which is equivalent to forming a part of the oxide layer 103 in advance, thereby reducing the time for forming the oxide layer 103 by the subsequent first laser treatment. In some embodiments, the thickness of the initial oxide layer 102 is in a range of 1 nm to 3 nm, for example, 1 nm, 2 nm or 3 nm. By setting the thickness of the initial oxide layer 102 within the range above, on the one hand, a part of the oxide layer 103 can be formed in advance, the time for forming the oxide layer 103 by the subsequent first laser treatment is reduced, and the efficiency of the first laser treatment is improved; on the other hand, the problem that the initial oxide layer 102 is poorly passivated due to the thick initial oxide layer 102, so that the subsequent first laser treatment cannot effectively perform deep oxidation can be avoided, thereby improving the passivation effect of the subsequently generated oxide layer 103.

Referring to FIG. 6, FIG. 6 is a structural schematic diagram of a solar cell obtained after the second oxidation treatment in an embodiment of the present disclosure. In the embodiment, the initial oxide layer 102 is subjected to a second oxidation treatment, and the initial oxide layer 102 is oxidized to the oxide layer 103.

In the present embodiment, after the initial oxide layer 102 is formed on the cross-section 101, the initial oxide layer 102 is subjected to the second oxidation treatment, so that both the thickness and density of the initial oxide layer 102 are increased to form the oxide layer 103, thereby forming the dense oxide layer 103 with a uniform thickness. Compared to the first preheating treatment, second oxidation treatment may generate an oxide layer 103 with a greater density, so as to fully saturate the dangling bonds of the Si—SiO₂ interface in the silicon substrate and improve the performances (including reducing recombination, improving carrier transport, increasing open pressure and filling, increasing power, etc.) of the generated split cell.

In some embodiments, the second oxidation treatment includes: subjecting the initial oxide layer 102 to a first laser treatment in an oxygen-rich environment. The oxygen-rich environment is an oxygen-containing liquid environment, so that the initial oxide layer 102 can be further oxidized to obtain a denser oxide layer. In the present embodiment, the first laser treatment may be implemented by using a red light continuous-wave laser or a green light continuous-wave laser, or may be implemented by using a picosecond laser or a nanosecond laser. The laser is perpendicular to the cross-section 101 and irradiates the cross-section 101. A shape of a light spot is circle-shaped or square-shaped. A diameter of the circle is in a range of 1 mm to 2 mm, or a size of the square is in a range of 1 mm to 2 mm. At the same time, hydrogen peroxide solution can be sprayed on a high-temperature cross-section 101 to provide an oxygen-rich environment on the cross-section 101, and a mass fraction the hydrogen peroxide solution is in a range of 30%-40%. In other embodiments, other oxygen-containing liquids, such as ozone aqueous solution, may also be sprayed on the cross-section.

In some embodiments, a power of the first laser treatment may be in a range of 150 W to 300 W, for example, the power of the first laser treatment may be 150 W, 200 W, 250 W or 300 W. Before the first laser treatment, the first preheating treatment is performed on the cross-section 101 so that the temperature of the cross-section 101 reaches the first preset temperature and the temperature distribution of the cross-section 101 is uniform. Therefore, the actual power of the first laser treatment may be low, and even if the power of the first laser treatment is set to be within the range described above, a uniform and dense oxide layer 103 can be formed on the cross section 101; meanwhile, when the power of the first laser treatment is set to be within the range described above, the negative effect of heat injure on the cross section 101 caused by laser can be reduced, and the performance of the generated split cell can be improved.

In some embodiments, during the first laser treatment processing, a scanning speed of the laser may be in a range of 1000 mm/s to 30000 mm/s, for example, the scanning speed of the laser may be 1000 mm/s, 1500 mm/s, 2000 mm/s, 2500 mm/s or 3000 mm/s. By setting the scanning speed of the laser within the range described above, on the one hand, the problem of uneven thickness of the generated oxide layer 103 caused by too fast scanning speed can be avoided; and on the other hand, the problem of excessive heat injure of the cross-section 101 caused by too slow scanning speed can be avoided, thereby improving the passivation effect of the generated oxide layer 103.

In some embodiments, a temperature of the first laser treatment may be in a range of 500 degrees centigrade to 1000 degrees centigrade, for example, the temperature of the first laser treatment may be 500 degrees centigrade, 600 degrees centigrade, 700 degrees centigrade, 800 degrees centigrade, 900 degrees centigrade or 1000 degrees centigrade. By setting the temperature of the first laser treatment within the range above, on the one hand, the density of the generated oxide layer 103 can be improved, and the passivation effect of the oxide layer 103 can be improved; and on the other hand, thermal build-up can be reduced, unnecessary heat injure to the split cell caused by an excessively high temperature of the first laser treatment can be avoided, and the performance of the generated split cell can be improved.

In some embodiments, a time of the first preheating treatment is longer than a time of the second oxidation treatment. With this arrangement, on the one hand, the temperature of the cross-section 101 obtained by the first preheating treatment can be relatively uniform, and the uniformity and density of the initial oxide layer 102 can be improved; on the other hand, since the cross-section 101 has been preheated by the first preheating treatment, even if the time of the second oxidation treatment is short, a dense oxide layer 103 with a uniform thickness can be generated, and at the same time, the problem of heat injure caused by the excessively high temperature of the first laser treatment processing can be avoided, and the performance of the split cell can be improved.

In some embodiments, the time of the first laser treatment may be in a range of 100 s to 500 s, for example, the time of the first laser treatment may be 100 s, 200 s, 300 s, 400 s or 500 s. By setting the time of the first laser treatment within the range above, on the one hand, it can be ensured that the generated oxide layer 103 has a uniform thickness and good density; and on the other hand, the problem of heat injure to the cross-section 101 caused by the excessively long time of the first laser treatment can be avoided, thereby improving the performance of the generated split cell.

In some embodiments, a thickness of the oxide layer 103 may be in a range of 5 nm to 10 nm, for example, the thickness of the oxide layer 103 may be 5 nm, 6 nm, 7 nm, 8 nm, 9 nm or 10 nm. By setting the thickness of the oxide layer 103 within the range above, on the one hand, a denser oxide layer 103 can be formed to improve the passivation effect of the oxide layer 103 and fully saturate the dangling bonds of the Si—SiO₂ interface in the silicon substrate; and on the other hand, insufficient diffusion of hydrogen ions in the subsequent hydrogen passivation activation treatment caused by excessive thick oxide layer 103 can be avoided, so that the hydrogen ions of the hydrogen-containing passivation layer can be effectively released to the cross-section 101 to passivate the damage zone of the cross-section 101, repair the internal defects of the cross-section 101, improve the passivation effect of the split cell, and improve the performance of the split cell.

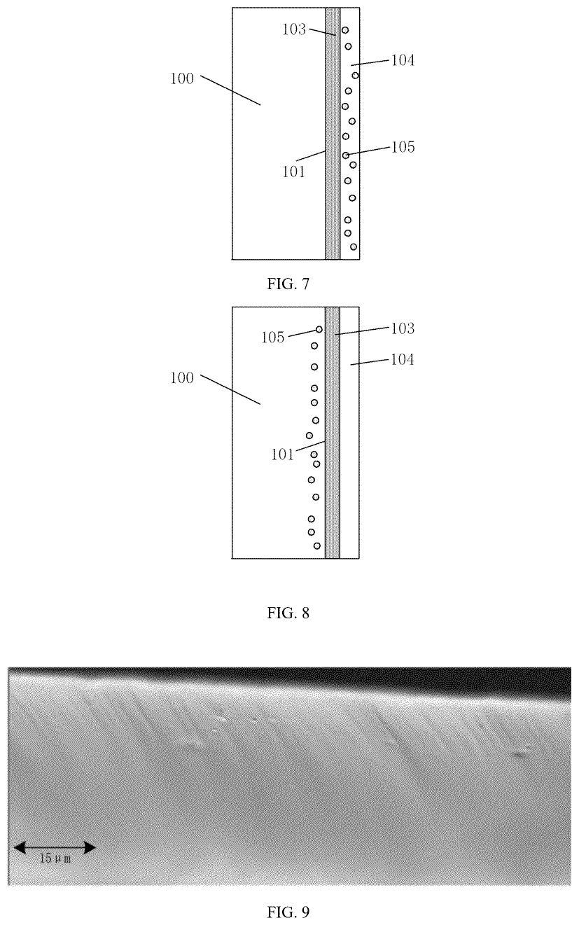

Referring to FIG. 7, FIG. 7 is a structural schematic diagram of a solar cell after preparing the hydrogen-containing passivation layer in an embodiment of the present disclosure. In some embodiments, a hydrogen-containing passivation layer 104 is prepared on a surface of the oxide layer 103 away from the cross-section.

In some embodiments, the hydrogen-containing passivation layer 104 is provided on the surface of the oxide layer 103 away from the cross-section to provide a source of hydrogen ions 105 for the subsequent hydrogen passivation activation treatment, so as to release hydrogen ions 105 in the hydrogen-containing passivation layer 104 to the cross-section 101 to passivate the damage zone of the cross-section 101, repair the internal defects of the cross section 101, improve the passivation effect of the split cell, and improve the performance of the split cell.

In some embodiments, the hydrogen-containing passivation layer may be deposited by ALD at a low temperature in the related art, or may be deposited by other methods, such as PECVD (Plasma Enhanced Chemical Vapor Deposition), CVD (Chemical Vapor Deposition), PCVD (Photo Chemical Vapor Deposition), PVD (Physical Vapor Deposition), laser-induced deposition, and the like.

In some embodiments, the hydrogen-containing passivation layer 104 may be made of aluminum oxide, and the hydrogen-containing passivation layer 104 may be made of other hydrogen-containing materials, such as hydrogenated silicon nitride, hydrogenated amorphous silicon, hydrogenated silicon oxide, titanium dioxide, zinc oxide and the like.

In some embodiments, a thickness of the hydrogen-containing passivation layer 104 may be greater than a thickness of the oxide layer 103. In this way, it can be ensured that the hydrogen-containing passivation layer 104 can provide enough hydrogen ions 105 to penetrate the oxide layer 103, so that the hydrogen ions 105 in the hydrogen-containing passivation layer 104 can be effectively released to the cross-section 101 to passivate the damage zone of the cross-section 101, repair the internal defects of the cross-section 101, and improve the passivation effect of the split cell.

In some embodiments, a thickness of the hydrogen-containing passivation layer 104 may be in a range of 5 nm to 50 nm, for example, the thickness of the hydrogen-containing passivation layer 104 may be 5 nm, 10 nm, 15 nm, 20 nm, 25 nm, 30 nm, 35 nm, 40 nm, 45 nm or 50 nm. By setting the thickness of the hydrogen-containing passivation layer 104 within the range above, on the one hand, the hydrogen-containing passivation layer 104 can provide a sufficient source of hydrogen ions 105, so that the hydrogen ions 105 in the hydrogen-containing passivation layer 104 can be effectively released to the cross-section 101 to passivate the damage zone of the cross-section 101, repair the internal defects of the cross-section 101, and improve the passivation effect of the split cell; on the other hand, in the subsequent second laser treatment process, the surface state density of the split cell can be effectively reduced, the surface defects of the split cell can be reduced, and the surface performance of the generated split cell can be improved.

The lower the deposition temperature of the hydrogen-containing passivation layer 104 is, the higher the content of hydrogen ions 105 in the hydrogen-containing passivation layer 104 is. In some embodiments, the process temperature for depositing the hydrogen-containing passivation layer 104 may be in a range of 200 degrees centigrade to 300 degrees centigrade, for example, the process temperature for depositing the hydrogen-containing passivation layer 104 may be 200 degrees centigrade, 210 degrees centigrade, 220 degrees centigrade, 230 degrees centigrade, 240 degrees centigrade, 250 degrees centigrade, 260 degrees centigrade, 270 degrees centigrade, 280 degrees centigrade, 290 degrees centigrade or 300 degrees centigrade. By setting the process temperature of depositing the hydrogen-containing passivation layer 104 within the range above, the temperature of depositing the hydrogen-containing passivation layer 104 is low, which can increase the content of hydrogen ions 105 in the hydrogen-containing passivation layer 104; and meanwhile, the low-temperature deposited hydrogen-containing passivation layer 104 can more effectively passivate defects on the surface of the split cell, and reduce the surface recombination rate of the sliced cell. In addition, by setting the process temperature for depositing the hydrogen-containing passivation layer 104 within the range above, the hydrogen ions 105 can be uniformly distributed in the hydrogen-containing passivation layer 104, so that in the subsequent second laser treatment process, the uniformly distributed hydrogen ions 105 can be uniformly diffused to the cross-section 101, thereby passivating the damage zone of the cross-section 101, repairing the internal defects of the cross-section 101, improving the passivation effect of the split cell, and improving the performance of the split cell.

In some embodiments, after the hydrogen-containing passivation layer 104 is deposited, the surface of the hydrogen-containing passivation layer 104 away from the oxide layer 103 is subjected to a second preheating treatment.

In this embodiment, by performing the second preheating treatment on the surface of the hydrogen-containing passivation layer 104 away from the oxide layer 103, the hydrogen-containing passivation layer 104 may be heated in advance, so that the hydrogen-containing passivation layer 104 is preheated to the second preset temperature, and the actual power of the subsequent second laser treatment is reduced, thereby reducing the negative effect of heat injure caused by the second laser treatment on the hydrogen-containing passivation layer 104, and improving the passivation effect of the generated hydrogen-containing passivation layer 104.

In some embodiments, a temperature of the second preheating treatment is lower than a temperature of the first preheating treatment, that is, the second preset temperature is lower than the first preset temperature. Since the subsequent second laser treatment is configured to release the hydrogen ions in the hydrogen-containing passivation layer 104 into the damage zone of the cross-section 101 to repair internal lattice defects, the power of the second laser treatment is small, and the corresponding temperature of the second preheating treatment is also low. The first laser treatment is configured to perform deep oxidation, and the second oxidation treatment requires a higher temperature, so that the power of the first laser treatment is greater than that of the second laser treatment, and the corresponding temperature of the first preheating treatment is also higher than that of the second preheating treatment. In this way, it can be ensured that the second preheating treatment can reduce the power of the subsequent second laser treatment, and it can also be ensured that the temperature of the second preheating treatment is lower, thereby reducing the negative effect of heat injure on the heat injure caused by the second preheating treatment to the hydrogen-containing passivation layer 104, and improving the passivation effect of the generated hydrogen-containing passivation layer 104.

In some embodiments, a temperature of the second preheating treatment may be in a range of 50 degrees centigrade to 100 degrees centigrade, for example, the temperature of the second preheating treatment may be 50 degrees centigrade, 60 degrees centigrade, 70 degrees centigrade, 80 degrees centigrade, 90 degrees centigrade or 100 degrees centigrade. By setting the temperature of the second preheating treatment within the range above, on the one hand, the hydrogen-containing passivation layer 104 can be preheated, the power of the subsequent second laser treatment can be reduced, and the damage to the hydrogen-containing passivation layer 104 caused by the excessive high power of the second laser treatment can be avoided; on the other hand, the rapid change of the temperature of the hydrogen-containing passivation layer 104 caused by the excessive high temperature of the second preheating treatment can also be avoided, it can ensure that the temperature of the hydrogen-containing passivation layer 104 is uniformly diffused, the performance difference caused by local overheating or undercooling of the hydrogen-containing passivation layer 104 can be reduced, the hydrogen-containing passivation layer 104 with uniform temperature can be provided for the subsequent second laser treatment, and the passivation effect of the generated split cell can be improved.

Referring to FIG. 8, FIG. 8 is a structural schematic diagram of a solar cell obtained after the hydrogen-passivation activation treatment in an embodiment of the present disclosure. In some embodiments, the surface of the hydrogen-containing passivation layer 104 away from the oxide layer 103 is subjected to hydrogen-passivation activation treatment, so as to release the hydrogen ions 105 in the hydrogen-containing passivation layer 104 to the cross-section 101 to obtain the passivated split cell piece.

In some embodiments, the hydrogen-containing passivation layer 104 is subjected to hydrogen-passivation activation treatment, so as to release hydrogen ions 105 in the hydrogen-containing passivation layer 104 to the cross-section 101 to passivate the damage zone of the cross-section 101, repair the internal defects of the cross section 101, improve the passivation effect of the split cell, and improve the performance of the split cell.

In some embodiments, the hydrogen-passivation activation treatment may be a second laser treatment. In the present embodiment, the second laser treatment may be implemented by using a red light continuous-wave laser or a green light continuous-wave laser, or may be implemented by using a picosecond laser or a nanosecond laser. The laser is perpendicular to the cross-section 101 and irradiates the hydrogen-containing passivation layer 104. A shape of a light spot is circle-shaped or square-shaped. A diameter of the circle is in a range of 1 mm to 2 mm, or a size of the square is in a range of 1 mm to 2 mm. The hydrogen ions 105 accumulated in the low-temperature hydrogen-containing passivation layer 104 can be activated, so that the hydrogen ions 105 can be released to the damage zone in the cross-section 101 and repair the internal lattice defects.

In some embodiments, an energy of the second laser treatment is lower than an energy of the first laser treatment. Since the first laser treatment is configured to perform deep oxidation to form the oxide layer 103, and the second laser treatment is configured to release hydrogen ions in the hydrogen-containing passivation layer 104 into the damage zone of the cross-section 101 to repair internal lattice defects, the energy of the first laser treatment is greater than that of the second laser treatment, that is, the power of the second laser treatment is lower than that of the first laser treatment, and the temperature of the second laser treatment is lower than that of the first laser treatment. In this way, the second laser treatment can release the hydrogen ions in the hydrogen-containing passivation layer 104 to the cross-section 101 to passivate the damage zone of the cross-section 101 and repair the internal defects of the cross-section 101, and meanwhile, the surface of the hydrogen-containing passivation layer 104 can be prevented from being damaged due to the excessive energy of the second laser treatment, thereby improving the performance of the split cell.

In some embodiments, the power of the second laser treatment may be in a range of 80 W to 150 W, for example, the power of the second laser treatment may be 80 W, 90 W, 100 W, 110 W, 120 W, 130 W, 140 W or 150 W. The second preheating treatment is performed on the cross-section 101 before the second laser treatment, so that the temperature of the hydrogen-containing passivation layer 104 reaches the second preset temperature and the temperature distribution of the hydrogen-containing passivation layer 104 is uniform. Thus, the actual power of the second laser treatment can be low, thereby reducing the power consumption of the second laser treatment, and even if the power of the second laser treatment is set within the range above, the hydrogen ions 105 enriched in the hydrogen-containing passivation layer 104 can be released to the cross-section 101; at the same time, since the second laser treatment is set within the range above, the negative effect of heat injure on the hydrogen-containing passivation layer 104 caused by the laser treatment can also be reduced, thereby improving the performance of the generated split cell.

In some embodiments, in the second laser processing, the scanning speed of the laser may be in a range of 1000 mm/s to 30000 mm/s, for example, the scanning speed of the laser may be 1000 mm/s, 1500 mm/s, 2000 mm/s, 2500 mm/s or 3000 mm/s. By setting the scanning speed of the laser within the range above, on the one hand, the problem that the hydrogen ions are unevenly released to the cross-section 101 due to excessively fast scanning speed of the laser can be avoided; and on the other hand, the problem of excessive heat injure to the hydrogen-containing passivation layer 104 due to too slow scanning speed of the laser can be avoided, thereby improving the quality of the surface of the hydrogen-containing passivation layer 104 and improving the passivation effect of the hydrogen-containing passivation layer 104.

In some embodiments, the temperature of the second laser treatment may be in a range of 300 degrees centigrade to 750 degrees centigrade, for example, the temperature of the second laser treatment may be 300 degrees centigrade, 350 degrees centigrade, 400 degrees centigrade, 450 degrees centigrade, 500 degrees centigrade, 550 degrees centigrade, 600 degrees centigrade, 650 degrees centigrade, 700 degrees centigrade or 750 degrees centigrade. By setting the temperature of the second laser treatment within the range above, on the one hand, the hydrogen ions 105 enriched in the low-temperature deposited hydrogen-containing passivation layer 104 can be activated to ensure that the hydrogen ions 105 of the hydrogen-containing passivation layer 104 can be quickly released into the damage zone of the cross-section 101 to repair internal lattice defects; on the other hand, the second preheating treatment is performed on the cross-section 101 before the second laser treatment, the temperature of the hydrogen-containing passivation layer 104 can reach the second preset temperature, so that the temperature of the second laser treatment is lower, and during the second laser treatment, thermal build-up can be reduced, unnecessary heat injure to the split cell caused by the excessively high temperature of the second laser treatment can be avoided, and the performance of the generated split cell can be improved.

In some embodiments, the method for preparing a solar cell may include following steps. Firstly, the cross-section 101 of the scribed initial split cell 100 is subjected to the first preheating treatment to obtain an initial oxide layer 102 with a thickness on the nanometer scale; then the initial oxide layer 102 is subjected to the first laser treatment, in which the initial oxide layer 102 is heated by instantaneously releasing a laser focused energy and strong oxidizing chemical reagents such as hydrogen peroxide solution are sprayed on the initial oxide layer 102 at the same time, so as to further enhance the internal diffusion of oxygen to the damage zone of the silicon substrate, saturate the Si—SiO₂ dangling bonds, form a denser oxide layer 103 and improve the passivation effect of the oxide layer 103; after the hydrogen-containing passivation layer 104 is deposited, the hydrogen-containing passivation layer 104 is subjected to the second laser treatment, and the hydrogen ions 105 enriched in the hydrogen-containing passivation layer 104 are activated to diffuse inward, thereby saturating the dangling bonds in the heat-affected zones and the crack damage zone generated in the first laser treatment during the scribing process, repairing the lattice defects, and improving the performance of the split cell.

In some embodiments, the solar cell is prepared by the method described above, compared with the solution of depositing a hybrid passivation layer with the ALD technology only in the related art, the performance of the generated split cell is further improved. Referring to FIG. 9, FIG. 9 is a structural schematic diagram of a hydrogen-containing passivation layer in an embodiment of the present disclosure. The hydrogen-containing passivation layer 104 obtained in the embodiments of the present disclosure has good density and good passivation effect, thereby improving the performances (including reducing recombination, improving carrier transmission, improving voltage opening and filling, improving power, etc.) of the generated split cell. Compared to the solar cell in the related art, the solar cell prepared by the method in the present disclosure has following improvements: the open voltage of the generated split cell is increased by 0.3 mV to 0.8 mV, the filling is increased by 0.05 to 0.15, the efficiency of the generated split cell is increased by 0.05% to 0.1%, and the power of the photovoltaic module made of the generated split cell is increased by 0.5 W to 1 W.

A solar cell is further provided in some embodiments of the present disclosure, which includes the passivated split cell piece prepared by the method for preparing the solar cell described above.

The split cell may include an initial split cell 100, and the initial split celll 100 may include a cross-section 101; an oxide layer 103 covering the cross-section; and a hydrogen-containing passivation layer 104 covering a surface of the oxide layer 103 away from the cross-section 101.

Referring to FIGS. 3 to 8, the split cell in the embodiments of the present disclosure are prepared by the method for preparing the solar cell described above. A cross-section 101 of the initial split cell is subjected to oxidation treatment to obtain an oxide layer 103, so as to saturate dangling bonds on the cross-section 103 and improve the passivation effect; after the hydrogen-containing passivation layer 104 is deposited on the oxide layer 103, a surface of the hydrogen-containing passivation layer 104 away from the oxide layer 103 is subjected to a hydrogen-passivation activation treatment, so as to release the hydrogen ions 105 in the hydrogen-containing passivation layer 104 to the cross-section 101, passivate a damage zone of the cross-section 101 and repair internal defects of the cross-section 101, and obtain a passivated split cell, thereby improving a passivation effect of the split cell and improve the performance of the split cell.

The solar cell of the present disclosure is assembled to form a photovoltaic module. In the process of assembling the photovoltaic module, welding strips are formed on the split cells, the split cells are welded together via the welding strips to form a solar cell string. A plurality of solar cell strings are connected in series or in parallel according to design requirements to form a complete solar cell module string, and then operations such as lamination, pressing, trimming, frame installation, junction box installation and the like are respectively performed to form the photovoltaic module. Since the photovoltaic module includes the solar cell of the present disclosure, the solar cell of the present disclosure has a good passivation effect, and the power of the photovoltaic module is improved. Those skilled in the art will understand that the above embodiments are specific implementations of the present application. In actual application, various modifications may be made to the form and details without departing from the spirit and scope of the present disclosure. The skilled in the art may make various alterations and modifications without departing from the spirit and scope of the present disclosure. Therefore, the scope of protection of the present application shall be determined by the scope defined in the claims. The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure. The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

What is claimed is:

1. A method for preparing a solar cell, the method comprising
providing an initial split cell with a cross-section;
subjecting the cross-section to an oxidation treatment to obtain an oxide layer;
preparing a hydrogen-containing passivation layer on a surface of the oxide layer away from the cross-section; and
subjecting a surface of the hydrogen-containing passivation layer away from the oxide layer to a hydrogen-passivation activation treatment, so as to release hydrogen ions in the hydrogen-containing passivation layer to the cross-section, to obtain a passivated split cell.

2. The method of claim 1, wherein the step of subjecting the cross-section to an oxidation treatment to obtain an oxide layer comprises: subjecting the cross-section to a first preheating treatment and preparing an initial oxide layer on the cross-section; and, subjecting the initial oxide layer to a second oxidation treatment, so that the initial oxide layer is oxidized to the oxide layer.

3. The method of claim 2, wherein the step of subjecting the cross-section to a first preheating treatment comprises: before the first preheating treatment, disposing the cross-section in an ozone environment to perform the first preheating treatment.

4. The method of claim 3, wherein in the step of disposing the cross-section in an ozone environment to perform the first preheating treatment, a concentration of ozone is in a range of 800 ppm to 1200 ppm.

5. The method of claim 2, wherein the step of the second oxidation treatment comprises: subjecting the initial oxide layer to a first laser treatment in an oxygen-rich environment.

6. The method of claim 5, wherein the oxygen-rich environment comprises an oxygen-containing liquid environment, and the oxygen-containing liquid is selected from the group consisting of hydrogen peroxide solution, ozone aqueous solution, and any combination thereof.

7. The method of claim 6, wherein the step of subjecting the initial oxide layer to the first laser treatment in the oxygen-rich environment comprise: spraying a hydrogen peroxide solution on the cross-section, and subjecting the initial oxide layer to the first laser treatment at the same time, wherein a mass fraction of the hydrogen peroxide solution is in a range of 30%-40%.

8. The method of claim 5, wherein the step of the hydrogen-passivation activation treatment comprises a second laser treatment, and an energy of the second laser treatment is lower than an energy of the first laser treatment.

9. The method of claim 2, wherein before the step of subjecting the surface of the hydrogen-containing passivation layer away from the oxide layer to the hydrogen-passivation activation treatment, the method for preparing the solar cell further comprises:
subjecting the surface of the hydrogen-containing passivation layer away from the oxide layer to a second preheating treatment.

10. The method of claim 1, wherein a thickness of the hydrogen-containing passivation layer is greater than a thickness of the oxide layer.

11. The method of claim 10, wherein a thickness of the oxide layer is in a range of 5 nm to 10 nm, and a thickness of the hydrogen-containing passivation layer is in a range of 5 nm to 50 nm.

12. The method of claim 5, wherein a power of the first laser treatment is greater than a power of the second laser treatment.

13. The method of claim 5, wherein a temperature of the first laser treatment is higher than a temperature of the second laser treatment.

14. The method of claim 12, wherein the power of the first laser treatment is in a range of 150 W to 300 W, and the power of the second laser treatment is in a range of 80 W to 150 W.

15. The method of claim 13, wherein the temperature of the first laser treatment is in a range of 500 degrees centigrade to 1000 degrees centigrade, and the temperature of the second laser treatment is in a range of 300 degrees centigrade to 750 degrees centigrade.

16. The method of claim 5, wherein a scanning speed of the first laser treatment is in a range of 1000 mm/s to 30000 mm/s; and a scanning speed of the second laser treatment is in a range of 1000 mm/s to 30000 mm/s.

17. The method of claim 9, wherein a temperature of the second preheating treatment is lower than a temperature of the first preheating treatment.

18. The method of claim 9, wherein the temperature of the first preheating treatment is in a range of 100 degrees centigrade to 300 degrees centigrade; and the temperature of the second preheating treatment is in a range of 50 degrees centigrade to 100 degrees centigrade.

19. The method of claim 2, wherein a time of the first preheating treatment is longer than a time of the second oxidation treatment.

20. The method of claim 19, wherein the time of the first preheating treatment is in a range of 600 s to 900 s; and the time of the second oxidation treatment is in a range of 100 s to 500 s.
